(19) United States
(12) Patent Application Publication
(10) Pub. No.: US 2024/0379571 A1
(43) Pub. Date: Nov. 14, 2024

(54) SEMICONDUCTOR PACKAGE WITH UNDER-BUMP METALLIZATION PROVIDING IMPROVED PACKAGE RELIABILITY

(71) Applicant: Taiwan Semiconductor Manufacturing Company, Hsinchu (TW)

(72) Inventors: Ting-Ting Kuo, Hsinchu (TW); Tien-Chung Yang, Hsinchu (TW); Li-Hsien Huang, Hsinchu (TW); Yao-Chun Chuang, Hsinchu (TW); Yinlung Lu, Hsinchu (TW)

(21) Appl. No.: 18/195,058

(22) Filed: May 9, 2023

(51) Int. Cl. H01L 23/538; H01L 21/48; H01L 23/00

(52) U.S. Cl. CPC H01L 23/5386; H01L 21/4846; H01L 24/13; H01L 24/16; H01L 24/29; H01L 24/32; H01L 24/73; H01L 24/81; H01L 24/83; H01L 24/92; H01L 23/3128; H01L 24/24; H01L 25/18; H01L 2224/13147; H01L 2224/1357; H01L 2224/16227; H01L 2224/24227; H01L 2224/2919; H01L 2224/32225; H01L 2224/73204; H01L 2224/81815; H01L 2224/83104; H01L 2224/83862; H01L 2224/92125; H01L 2924/1431; H01L 2924/1436; H01L 2924/19041; H01L 2924/19106; H10B 80/00

(57) ABSTRACT

A method of manufacturing a semiconductor package includes forming an under-bump metallization, and forming a redistribution layer. The redistribution layer includes a plurality of metallization layers embedded in intermetal dielectric material. The metallization layers of the redistribution layer electrically connect a semiconductor die with the under-bump metallization. The under-bump metallization includes a bonding pad and a guard ring encircling the bonding pad. The guard ring forms an annular pocket encircling the bonding pad. The annular pocket is filled with a polymer material. A crack formed in underfill material coating a bonding bump bonded to the bonding pad is blocked from penetrating into the redistribution layer using the guard ring.

### BACKGROUND

The following relates to the semiconductor packaging arts, multiple-die packaging arts, package-on-package (POP) arts, wafer bonding arts, package bonding arts, under-bump metallization (UBM) arts, corresponding semiconductor and package manufacturing arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a side sectional view of a bonding bump diagrammatically showing potential impact of stress and/or underfill cracking and suppression of the impact of such stress and/or cracking by modification of the UBM.

FIG. 2 diagrammatically illustrates side sectional and top views of an under-bump metallization (UBM) for a single bonding bump implementing the modification diagrammatically shown in FIG. 1.

FIGS. 3, 4, 5, 6, 7, 8, 9, 10, 11, and 12 diagrammatically illustrate cross-sectional views of selected steps during fabrication of a bottom-only integrated fanout (InFO-b) package.

FIGS. 13, 14, and 15 diagrammatically illustrate cross-sectional views of two selected steps during attachment of a semiconductor component on the package component fabricated in accordance with FIGS. 3-9.

FIG. 16 diagrammatically illustrates side sectional and top views of an under-bump metallization (UBM) for a single bonding bump according to a further embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A wide range of semiconductor packages employ ball grid arrays (BGAs) for connecting two semiconductor dies, semiconductor packages, or various combinations thereof. For example, a BGA may be used to connect a dynamic random access memory (DRAM) chip to a semiconductor package, or a package-on-package (POP) assembly may be fabricated. In a semiconductor package, a semiconductor die is embedded in a dielectric molding that includes front-side and backside electrical redistribution layers (RDL's) providing fanout of contacts of the embedded wafer or chip, and a dielectric interlayer with through-vias (TV's) electrically interconnecting the front and back RDL's. As one nonlimiting illustrative example, the embedded semiconductor die of the InFO package may be a logic integrated circuit (IC) chip, one of the RDLs may provide the mounting surface for mounting the InFO package onto a circuit board or the like, and the opposite-side RDL may be bonded to one or more DRAM dies or packages, thereby forming a computing system with tightly integrated logic and memory that is suitable for use in a cellular telephone (cellphone) or other mobile device, as a nonlimiting illustrative use case. A variant of this design is the bottom-only InFO package (i.e., InFO-b package), which is manufactured at a semiconductor foundry but has one RDL designed to enable the DRAM attachment (or more generally, attachment of a second semiconductor die or package) at a customer site or other third-party site. To enable this approach, the RDL to which the DRAM is to be attached is modified to provide a transport-stable surface with solderable pads, e.g. coated with pre-solder. The InFO-b package is shipped to the third party, where the second component is bonded onto the RDL of the InFO-b package via an under-bump metallization (UBM). This arrangement significantly increases flexibility by, for example, enabling the customer to install a custom in-house semiconductor die or package, enabling the customer to install different DRAM chips on different InFO-b packages to provide products with different memory capacities, and so forth.

As used herein, the under-bump metallization (UBM) is disposed on the surface of the redistribution layer (or, more generally, on a surface of the semiconductor package) and is designed to provide for electrical connection with another (i.e. second) semiconductor die or package via electrically conductive bonding bumps disposed on the bonding pads of the UBM. However, at a given stage of manufacturing the bonding bumps may not yet be disposed on the bonding pads. For example, an InFO-b package may be sold to a customer with pre-solder disposed on the bonding pads of the UBM. Moreover, as used herein “under” merely indicates the bonding bumps attach to the UBM, but does not connote any spatial “up” or “down” orientation. For example, the semiconductor package with the UBM could be attached to an underlying package using bonding bumps that attach to bonding pads of the UBM.

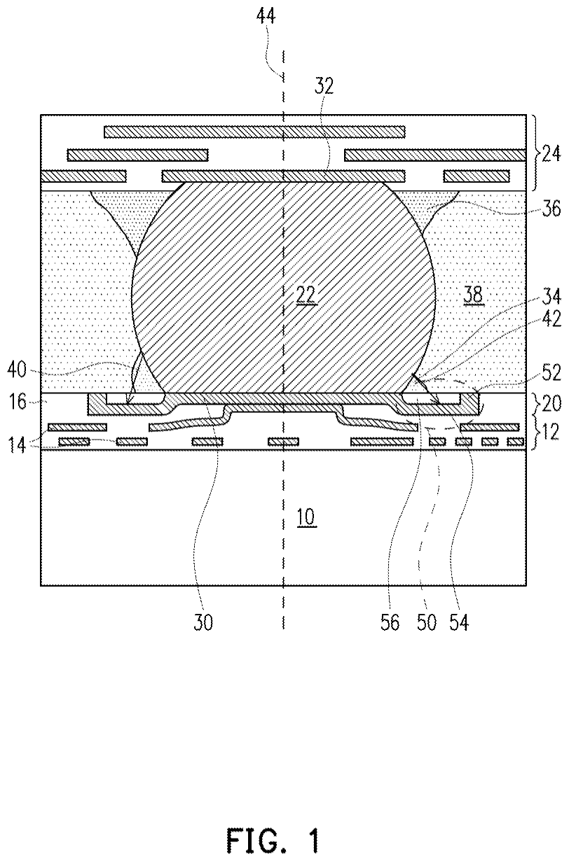

With reference now to FIG. 1, an example of such an attachment is shown. FIG. 1 a side sectional view of a portion of a diagrammatically indicated semiconductor package 10 along with an illustrated portion of a re-distribution layer (RDL) 12 of the semiconductor package 10. The RDL 12 includes a plurality of metallization layers 14 (only two of which are shown in diagrammatic FIG. 1) embedded in intermetal dielectric material 16. The RDL 12 has or includes an under-bump metallization (UBM) 20 disposed on a surface of the RDL 12. The metallization layers 14 and the UBM 20 comprise an electrically conductive material such as copper, aluminum, a copper alloy, or an aluminum alloy. FIG. 1 shows only a small portion of the UBM 20 corresponding to the bonding site of a single illustrative bonding bump 22. FIG. 1 further illustrates a portion of a second component 24 that is bonded to the semiconductor package 10 via the illustrated bonding bump 22. It will be appreciated that the illustrated bonding bump 22 is typically one bonding bump of a set of bonding bumps, sometimes called a ball grid array (BGA). The second component 24 may, for example, be a second semiconductor package, or a semiconductor die, or could be another type of component such as a circuit board. As shown in FIG. 1, the UBM 20 includes a bonding pad 30 to which the bonding bump 22 is bonded, and similarly the second component 24 includes a second bonding pad 32 to which the bonding bump 22 is also bonded, thus enabling the bonding bump 22 to attach (or contribute to attaching) the second component 24 to the semiconductor die 10. The bonding bump 22 may be a solder ball, or a copper ball coated with solder, or so forth. Additionally, solder flux is used to facilitate the solder bond of the bonding bump 22 to the bonding pads 30 and 32. The solder flux may be incorporated into the solder bulk or coating of the bonding bump 22, or may be coated onto the bonding bump 22 and/or one or both of the bonding pads 30 and/or 32. After the bonding, some solder flux residue 34 and 36 typically remains. The solder flux residue 34 surrounds the bond between the bonding bump 22 and the bonding pad 30 of the semiconductor package 10, and may for example constitute at least in part solder flux that was pushed out or expelled from that interface during the attachment process. Likewise, the solder flux residue 36 surrounds the bond between the bonding bump 22 and the bonding pad 32 of the second component 24, and may for example constitute at least in part solder flux that was pushed out or expelled from that interface during the attachment process. Furthermore, after the bonding, underfill material 38 is typically injected, applied by capillary action, or otherwise disposed in the space between the UBM 20 of the semiconductor package 10 and the second component 24. The underfill material 38 surrounds the bonding bumps including the illustrative bonding bump 22 and helps to stabilize the bonding and prevent ingress of contaminants that might degrade the electrical and structural connections provided by the bonding bumps. The underfill material 38 is typically injected or otherwise disposed in a liquid or viscous flowing material and then cured by a heating step. The underfill material 38 is an electrically nonconductive material such as a resin or other polymer so as to avoid presenting an electrical shunt between the bonding bumps of the BGA.

In a bonding situation such as that diagrammatically shown in FIG. 1, a problem can arise. The vicinity of the bonding bump 22 includes different types of materials, e.g. solder material in the case of some embodiments of the bonding bump 22, copper, aluminum, or another metal in the case of the bonding pads 30 and 32, the intermetal dielectric material 16 of the RDL 12, and the solder flux residue 36. These materials have significantly different properties, such as different coefficient of thermal expansion (CTE) values, different surface and interfacial properties, different chemical properties, and so forth. These differences can result in formation of cracks in the underfill material 38, especially at or near to the solder flux residue 34. FIG. 1 diagrammatically illustrates two such cracks 40 and 42 as arrows.

With particular reference now to the portion of diagrammatic FIG. 1 to the left of vertical divider 44, as the underfill 38 has some similarities with the intermetal dielectric material 16 of the RDL 12 and is in intimate contact therewith, the crack 40 can propagate into the intermetal dielectric material 16 and damage the RDL 12. Such crack propagation into the RDL 12 can degrade the RDL 12 and result in structural and/or electrical failure of the semiconductor package.

With particular reference now to the portion of diagrammatic FIG. 1 to the right of vertical divider 44, in embodiments disclosed herein the type of package failure produced by the crack 40 is prevented by a modification of the UBM 20 disclosed herein. In this modification, the UBM 20 includes a guard ring 50 that encircles the bonding pad 30. In the illustrative example of FIG. 1, the guard ring 50 includes an annular ring 52 encircling the bonding pad 30, and a buried connector ring 54 connecting between the bonding pad and the annular ring. The guard ring 50 forms an annular pocket encircling the bonding pad 30. The annular pocket is filled with a polymer material 56. In some embodiments, the polymer material 56 is the same material as the intermetal dielectric material 16 of the RDL 12, although this is not required.

A corresponding method of manufacturing the semiconductor package of FIG. 1 with the guard ring 50 includes forming the UBM 20, and forming the RDL 12. The RDL 12 includes a plurality of metallization layers 14 embedded in the intermetal dielectric material 16. The metallization layers 14 of the RDL 12 electrically connect a semiconductor die (not shown in FIG. 1) with the UBM 20. The UBM 20 includes the bonding pad 30 and the guard ring 50 encircling the bonding pad 30. The guard ring 50 forms the annular pocket encircling the bonding pad 30. The annular pocket is filled with the polymer material 56. A crack formed in the underfill material 38 coating the bonding bump 22 bonded to the bonding pad 30 is blocked from penetrating into the RDL 12 using the guard ring 50.

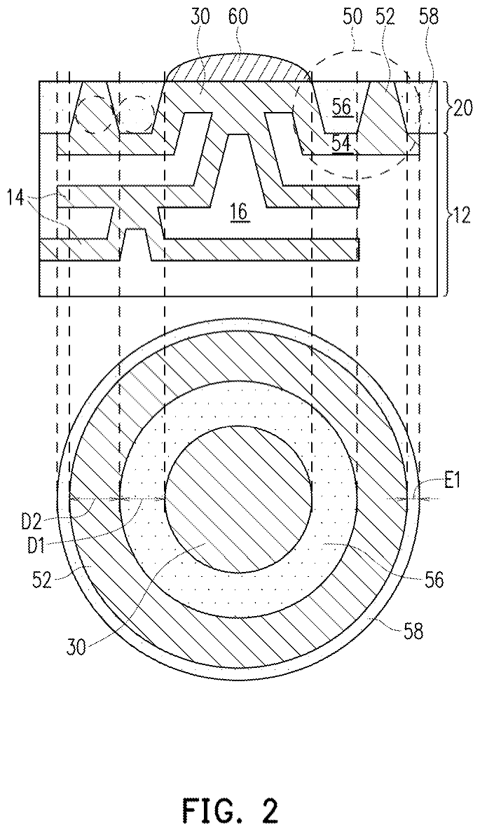

With reference now to FIG. 2, a side sectional view (upper drawing) and top view (bottom drawing) is shown of an embodiment of the portion the UBM 20 corresponding to a single bonding bump disposed on the RDL 12, illustrating in greater detail the modification just described with reference to the portion of FIG. 1 to the right of the vertical divider 44. FIG. 2 illustrates the guard ring 50 including the annular ring 52 encircling the bonding pad 30, and the buried connector ring 54 (only visible in the side sectional view) connecting between the bonding pad 30 and the annular ring 52, along with the polymer material 56 filling the annular pocket encircling the bonding pad 30. Again, the annular pocket containing the polymer material 56 is bounded by the outer periphery of the bonding pad 30, the annular ring 52, and the connecting ring 54. The top view of FIG. 2 best illustrates the annulus geometry of the annular ring 52 encircling the bonding pad 30 and the annulus geometry of the polymer material 56 filling the pocket. Because these features 52, 54, and 56 encircle the bonding pad 30, they provide protection against propagation of cracks from the underfill into the RDL 12 around the full 360 degree circumference of the bonding pad 30. Optionally, as seen in FIG. 2 the same polymer material that makes up the polymer material 56 filling the pocket may also be disposed around the outside of the guard ring 50, as indicated by reference number 58 in FIG. 2. Optionally, this additional polymer material 58 may form a continuous polymer layer extending between the bonding pads 30 (with their encircling guard rings 50) of the UBM 20.

Note that FIG. 2 differs from FIG. 1 in that the second component 24 shown bonded in FIG. 1 is not present in FIG. 2. FIG. 2 may, for example, diagrammatically illustrate the state of an InFO-b package as it is shipped to a customer, i.e. before the DRAM or other second component is bonded onto the UBM 20. To this end, the side sectional view of FIG. 2 diagrammatically shows pre-solder 60 disposed on the bonding pad 30, as is sometimes done to prepare the surface of an InFO-b package for customer bonding of the DRAM or other second component. (Note further that the pre-solder 60 is not shown in the top view of FIG. 2).

The dimensions of the guard ring 50 should be large enough to ensure that cracks in the underfill material 38 near the solder flux residue 34 are captured by the polymer material 56 in the pocket of the guard ring 50. On the other hand, as the guard ring 50 encircles the bonding pad 30 it increases the effective diameter of the bonding pad thus reducing the achievable packing density of bonding pads of the UBM 20 and consequently reducing the packing density of the BGA. Based on these considerations of ensuring capture of cracks propagating from the proximity of the solder flux residue 34 around the bonding pad 30 while still maximizing packing density, in some nonlimiting illustrative embodiments the annulus of the annular pocket filled with the polymer material 56 (and hence also the annulus of the polymer material 56) has a width D1 indicated in FIG. 2 of between 30 microns and 40 microns inclusive, and an annulus of the annular ring 52 has a width D2 of between 10 microns and 40 microns inclusive. In some nonlimiting embodiments, the polymer material 58 disposed around the outside of the guard ring 50 forms an annulus having a width of between 7 microns and 14 microns exclusive. Alternatively, as previously noted this polymer material 58 could form a continuous planar layer extending between the bonding bump sites. The foregoing values are to be understood as nonlimiting illustrative examples, and more generally the optimal values for D1, D2, and (if relevant) E1 can be chosen based on empirical experiments to determine sufficiently large values for the widths DI and D2 to ensure sufficient crack capture to provide a desired package yield.

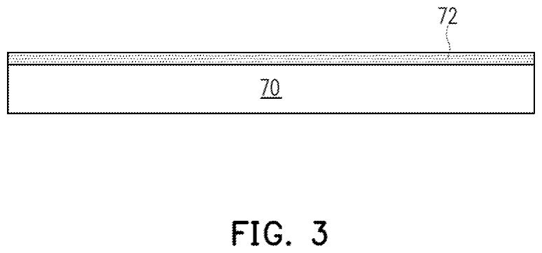

In the following and with successive reference to FIGS. 3-12, an illustrative example of a package fabrication workflow for fabricating an InFO-b package employing the guard rings 50 described with reference to FIGS. 1 and 2 is shown by way of diagrammatic cross-sectional views of the under-fabrication device at successive steps of the workflow.

Starting with FIG. 3, a carrier substrate 70 is provided, on which a polymer layer 72 is disposed. The carrier substrate 70 will ultimately be detached and discarded, hence it can be substantially any substrate with sufficient rigidity and a sufficiently planar surface. For example, the carrier substrate 70 can be a silicon substrate, a sapphire substrate, or so forth. The polymer layer will be processed to form the polymer material 56 that ultimately fills the annular pockets of the guard rings 50 surrounding the respective bonding pads 30 and the surrounding polymer material 58; hence the polymer layer 72 is made of that polymer material. Although not shown, in some embodiments an adhesive coating is interposed between the surface of the carrier substrate 70 and the polymer layer 72, which will later be dissolved using a laser process or the like to de-bond the carrier substrate 70 from the polymer layer 72.

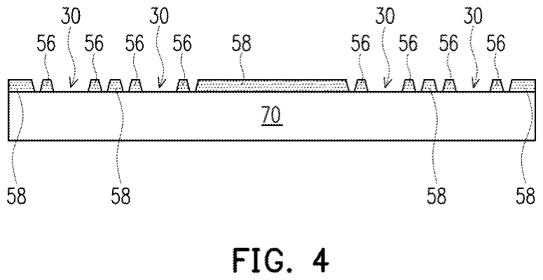

With reference now to FIG. 4, the polymer layer 72 is then photolithographically processed by depositing a photoresist layer on the polymer layer 72, exposing the polymer layer via a photolithographic mask to impart a latent image onto the photoresist layer, developing the photoresist to form a pattern of openings in the photoresist, and selectively etching the polymer layer 72 through the photoresist openings. As shown in the cross-sectional view of FIG. 4, this processing isolates and leaves portions of the original polymer layer 72 which are the polymer material 56 that ultimately fills the annular pockets of the guard rings 50 surrounding the respective bonding pads 30 and the surrounding polymer material 58. The patterned polymer layer has openings 300 corresponding to the bonding pads and encircling guard rings 50. The remaining polymer regions 56 and 58 are then cured.

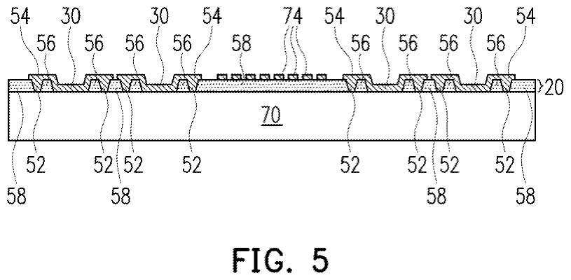

With reference now to FIG. 5, the under-bump metallization (UBM) 20 is formed on the patterned polymer layer (now comprising the remaining polymer regions 56 and 58) and in the openings 300 corresponding to the bonding pads and the guard rings. In one nonlimiting illustrative embodiment in which the UBM 20 comprises copper, this processing entails depositing a suitable blanket seed layer such as a seed layer of TiCu, depositing a photoresist layer on the blanket seed layer, exposing the photoresist using a suitable photomask, development of the resultant latent image to form openings corresponding to the UBM 20, performing copper plating through those openings to form the UBM 20, and stripping the photoresist. The resulting structure is shown by way of diagrammatic cross-section in FIG. 5, and includes the bonding pads 30, the encircling guard rings 50 (including the annular ring 52 and connecting rings 54 forming the pockets which are filled with the polymer regions 56), and the additional polymer material 58. Optionally, the patterning may form additional copper regions 74 in the field corresponding to the additional polymer material 58 as further shown, which can serve as a first metallization level of the RDL to be fabricated next.

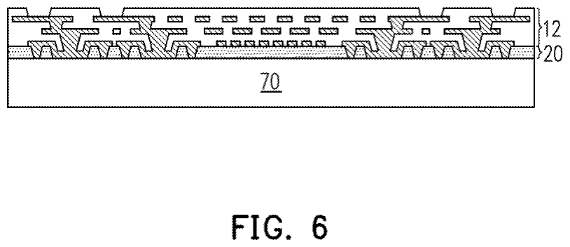

With reference now to FIG. 6, the RDL 12 is fabricated on the UBM 20. This entails multiple iterations, each including depositing a blanket layer of the intermetal dielectric material 16, performing photolithographic patterning to define vias through the blanket intermetal dielectric layer, filling the vias with via material, depositing and photolithographically patterning a metallization layer electrically connected with the vias, and repeating. The number of iterations corresponds to the number of metallization layers making up the RDL 12.

In some embodiments, the intermetal dielectric material 16 of the RDL 12 may be the same material as the polymer material 56 and 58 of the UBM 20, although this is not required. In some embodiments in which the intermetal dielectric material 16 of the RDL 12 is a transparent material, the polymer material 56 and 58 of the UBM 20 may be a gray polymer that includes a coloring additive. The optional use of a gray polymer as the polymer material 56 and 58 of the UBM 20 advantageously enables imprinting a readable label on the field polymer material 58, such as a batch number label or the like.

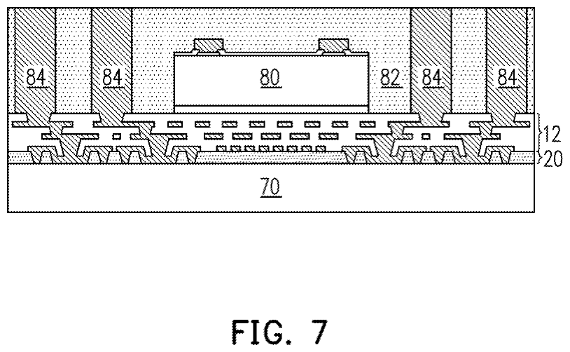

With reference now to FIG. 7, after formation of the RDL 12 a semiconductor die 80 is disposed on the RDL 12 (specifically on an opposite surface of the RDL 12 from the surface at which the UBM 20 is located), molding compound 82 is disposed around the placed semiconductor die 80, and through-vias (TV's) 84 are formed passing through the molding compound 82 to electrically contact the RDL 12. The placement of the semiconductor die 80 may also optionally electrically connect bonding pads of the semiconductor die 80 with contact pads of the surface of the RDL 12 opposite from the UBM 20. The semiconductor die 80 can be any chosen semiconductor device, such as a silicon integrated circuit (IC) die, for example a logic die.

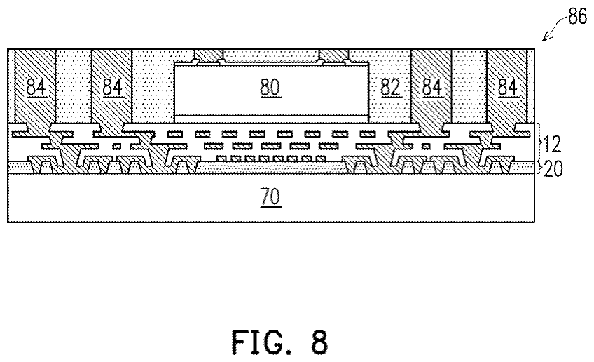

With reference now to FIG. 8, molding compound grinding is performed to planarize a surface 86 of the under-fabrication semiconductor package.

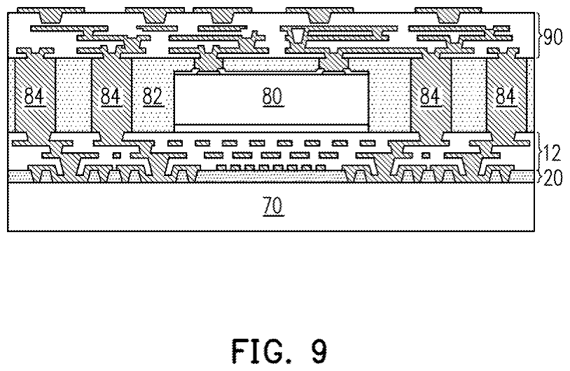

With reference now to FIG. 9, a second RDL 90 is formed on the planarized surface 86. This entails multiple iterations, each including depositing a blanket layer of the intermetal dielectric material 16, performing photolithographic patterning to define vias through the blanket intermetal dielectric layer, filling the vias with via material, depositing and photolithographically patterning a metallization layer electrically connected with the vias, and repeating. The number of iterations corresponds to the number of metallization layers making up the second RDL 90.

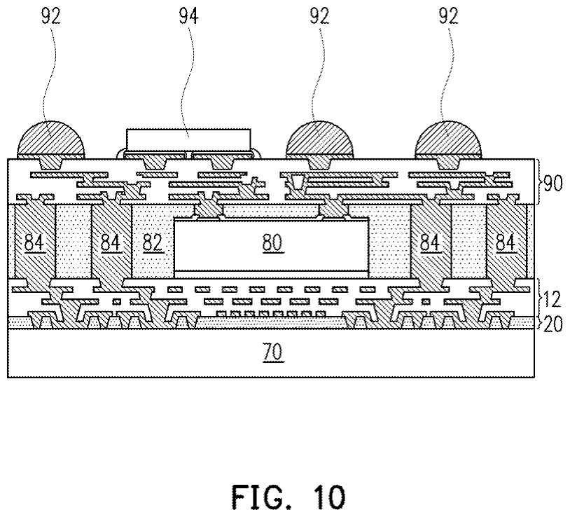

With reference now to FIG. 10, a ball grid array (BGA) of bonding bumps 92 is disposed on bonding pads of the exposed surface of the second RDL 90. Optionally, one or more integrated passive device (IPD) components may also be mounted on the exposed surface of the second RDL 90, such as an illustrative back end-of-line (BEOL) capacitor 94. Although not shown, a further underfill material optionally may be dispensed on the exposed surface of the second RDL 90 and around the bonding bumps 92 and IPD component(s) (if any).

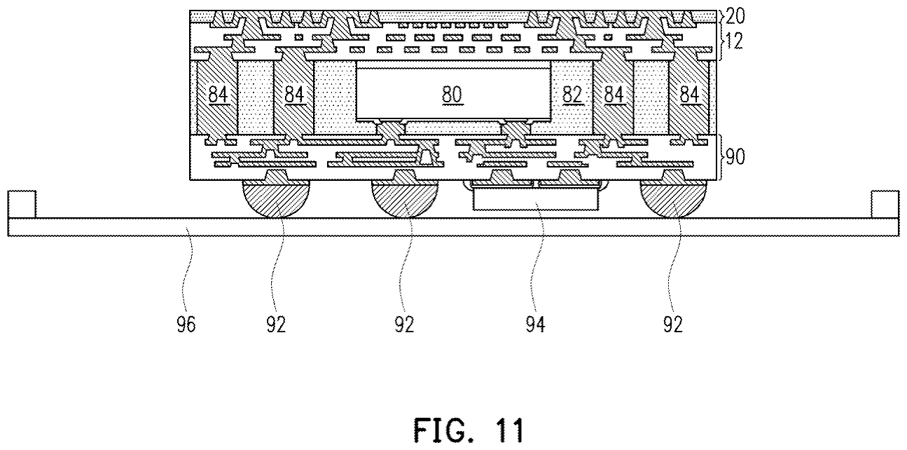

With reference now to FIG. 11, the bonding bumps 92 are bonded to frame tape or another support 96, and the carrier substrate 70 is de-bonded and removed. For example, if an adhesive coating was interposed between the surface of the carrier substrate 70 and the polymer layer 72 (as described previously with reference to FIG. 3), then the adhesive layer may now be dissolved using a laser process or the like to de-bond the carrier substrate 70 from the polymer layer 72. A post-laser de-bond cleaning process (PLDC) may optionally be performed to clean the surface exposed by the de-bonding of the carrier substrate. As seen in FIG. 11, the removal of the carrier substrate 70 and optional PLDC exposes the surface of the UBM 20 that is distal from the RDL 12.

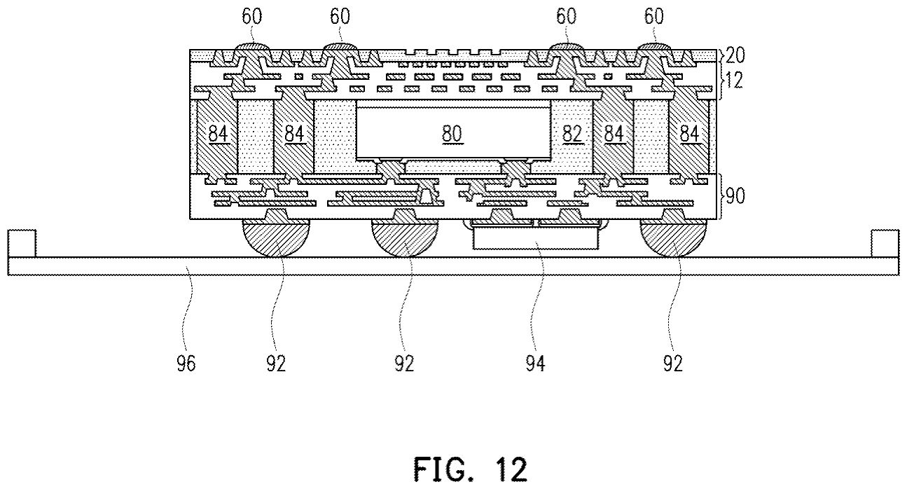

With reference now to FIG. 12, the pre-solder 60 is applied to the bonding pads 30 of the UBM 20 (see the cross-sectional view of FIG. 2 and corresponding description for a more detailed drawing and description thereof). This completes fabrication of the InFO-b package, which is now suitable for shipping to a customer or other third party. It is expected that the customer or other third party will complete the manufacturing process of a functional semiconductor package by mounting a DRAM or other second component 24 (cf. FIG. 1, e.g., second semiconductor die or second semiconductor package) on the bonding pads of the UBM 20.

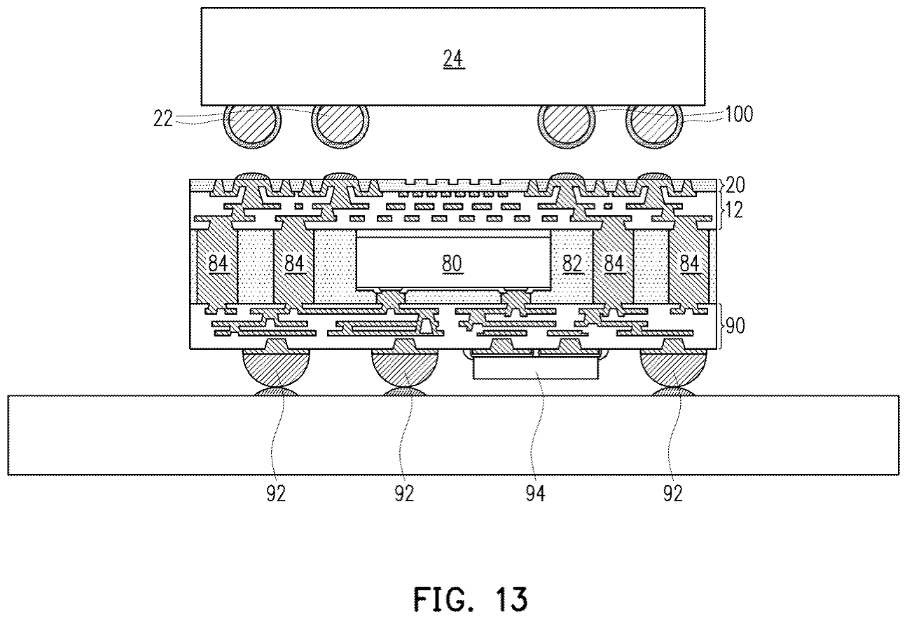

In the following and with successive reference to FIGS. 13-15, an illustrative example of the process that might be performed by the customer or other third party to mount the DRAM or other second component 24 on the UBM 20 is shown by way of diagrammatic cross-sectional views of the under-fabrication device at successive steps of the process.

Starting with FIG. 13, the DRAM or other second component 24 is illustrated in position to be placed on the UBM 20. In this illustrative example, the bonding bumps 22 are first disposed on the bonding pads of the second component 24 (e.g., on the illustrative bonding pad 32 shown in FIG. 1), and the bonding will then be completed by subsequently bonding the bonding bumps 22 to the bonding pads of the UBM 20. However, in other embodiments it is contemplated for the bonding bumps to be first disposed on the bonding pads of the UBM 20, and for the bonding to be completed by subsequently bonding the bonding bumps to the bonding pads of the second component. Notably, the bonding bumps 22 are coated with solder flux 100.

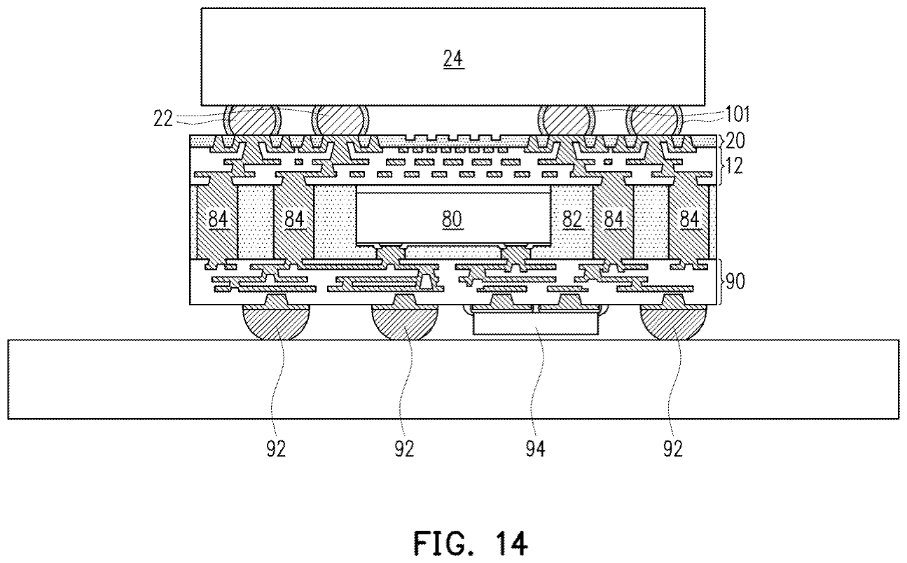

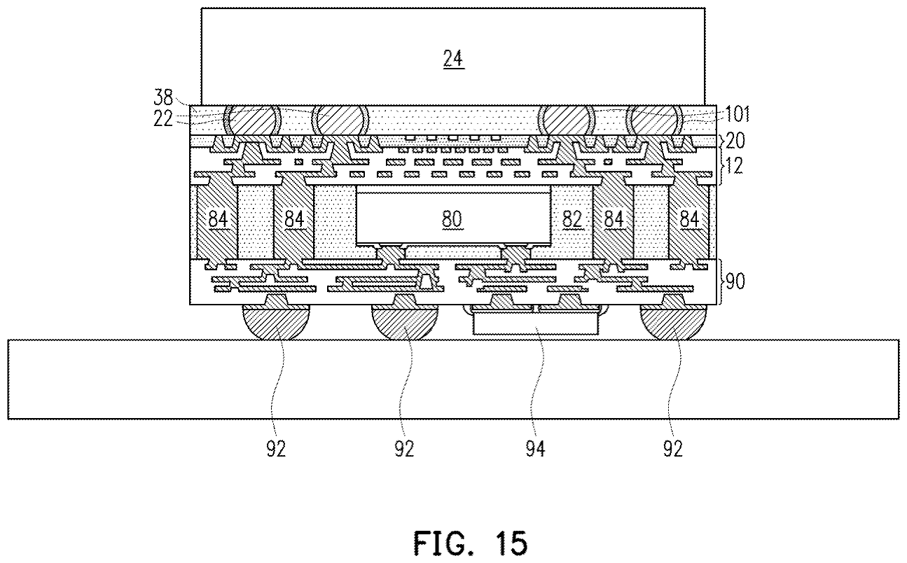

With reference now to FIG. 14, the DRAM or other second component 24 is illustrated now bonded to the UBM 20 of the InFO-b semiconductor package. The bonding process leaves some solder flux residue 101 on the solder bumps 22 after the attachment is complete. It is noted that while FIG. 15 illustrates a single second component 24 (e.g. a single DRAM) being bonded to the UBM 20 of the InFO-b package, in other embodiments two or more second components (e.g. two or more DRAMs) may be bonded to the UBM 20.

With reference now to FIG. 15, the underfill 38 is injected or otherwise disposed between the UBM 20 and the second component 24, thus completing the process.

The mounting process typically includes one or more heating steps, such as a heating step to achieve solder reflow to complete the bonding shown in FIG. 14, and/or a heating step to cure the underfill material 38 shown in FIG. 15. As previously discussed with reference to FIG. 1, due to the solder flux residue 101 on the solder bumps 22 after the attachment, such heating can lead to cracks forming due to differences in CTE and/or other mechanisms, especially in the vicinity of the solder flux residue 101. Advantageously, propagation of such cracks in the underfill material 38 around the bonding bumps 22 into the RDL 12 is blocked by the polymer material 56 filling the annular pocket encircling the bonding pad 30. More particularly, the cracks may propagate into the polymer material 56, but that polymer material 56 is contained in the annular pocket of the guard ring 50 and hence cannot propagate further into the RDL 12. This improves package yield. In the context of an InFO-b process, this yield improvement is especially significant since the failure mode would occur when the customer or other third party is mounting the DRAM or other second component 24 onto the InFO-b package received from the semiconductor foundry. Hence, in this failure mode the customer will perceive the situation as the semiconductor foundry shipping a defective InFO-b package (even though the failure actually occurred at the customer site).

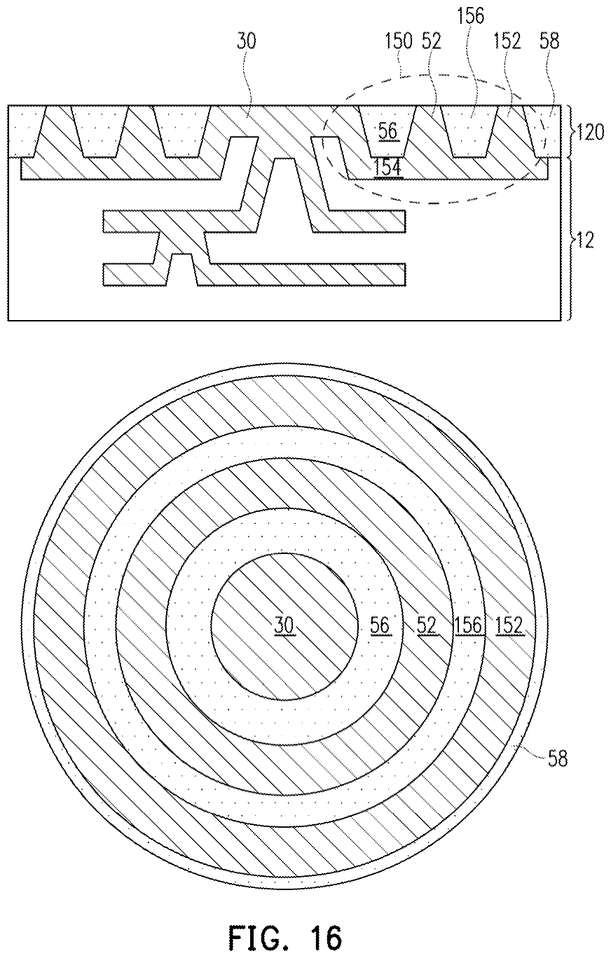

With reference now to FIG. 16, a side sectional view (upper drawing) and top view (bottom drawing) is shown of another embodiment of a portion a UBM 120 corresponding to a single bonding bump disposed on the RDL 12. FIG. 16 illustrates a guard ring 150 which according to this illustrative embodiment includes the annular ring 52 encircling the bonding pad 30, and a modified buried connector ring 154 (only visible in the side sectional view) connecting between the bonding pad 30 and the annular ring 52, along with the polymer material 56 filling the annular pocket encircling the bonding pad 30. Again, the annular pocket containing the polymer material 56 is bounded by the outer periphery of the bonding pad 30, the annular ring 52, and the connecting ring 54. However, unlike the embodiment of FIG. 2, in the embodiment of FIG. 16 the guard ring 150 further includes a second annular ring 152 encircling the (first) annular ring 52, and the modified buried connector ring 154 further connects between the annular ring 52 and the second annular ring 152, thus forming a second annular pocket that is again filled with (second) polymer material 156. The pocket containing the (second) polymer material 156 is bounded by the annular ring 52, the second annular ring 152, and the modified connecting ring 154.

The top view of FIG. 16 best illustrates the annulus geometry of the second annular ring 152 encircling the (first) annular ring 52 and the annulus geometry of the (second) polymer material 156 filling the second pocket bounded by the annular ring 52, the second annular ring 152, and the modified connecting ring 154. The second annular ring 152 and second polymer material 156 encircle the bonding pad 30 at a further radial distance away from the bonding pad 30 as compared with the (first) annular ring 52 and (first) polymer material 56, thus increasing the distance over which protection against propagation of cracks from the underfill into the RDL 12 is provided. Optionally, as seen in FIG. 16 the same polymer material that makes up the polymer material 56 and 156 filling the respective first and second pockets may also be disposed around the outside of the guard ring 150, as indicated by reference number 58 in FIG. 16. Optionally, this additional polymer material 58 may form a continuous polymer layer extending between the bonding pads 30 (with their encircling guard rings 150) of the UBM 20.

The guard ring 50 of FIG. 1 includes one pocket formed by the periphery of the bonding pad 30, the annular ring 52, and the connecting ring 54, and this pocket contains the polymer material 56. The guard ring 150 of FIG. 16 further includes the second pocket formed by the annular ring 52, second annular ring 152, and modified connecting ring 154 and this second pocket contains the polymer material 156. Although not illustrated, it is contemplated to further include a third pocket formed by second annular ring 152, a third annular ring at larger radius than the second annular ring, and a further modified connecting ring that extends between the second annular ring 154 and the third annular ring, and this third pocket would also contain polymer material. Extension to a fourth or more pockets is similarly contemplated.

In the illustrative embodiments, the bonding pad 30 has a circular periphery and the annular ring 52 and optional second annular ring 152 are circular annuluses that encircle the bonding pad, and the annular pocket is a circular annular pocket encircling the bonding pad. Although not illustrated, noncircular geometries are also contemplated. For example, the bonding pad could have a square periphery, and the corresponding annular ring or annular rings is/are then suitably a square annular ring or square annular rings encircling the square bonding pad, and the annular pocket or annular pockets is/are then suitably a square annular pocket or annular pockets encircling the square bonding pad.

In the following, some further embodiments are described.

In a nonlimiting illustrative embodiment, a semiconductor package comprises: a semiconductor die; a redistribution layer comprising a plurality of metallization layers and intermetal dielectric material; an under-bump metallization disposed on the redistribution layer, the metallization layers of the redistribution layer electrically connecting the semiconductor die with the under-bump metallization, wherein the under-bump metallization includes a bonding pad and an annular ring encircling the bonding pad; and an annular structure comprising a polymer material between the bonding pad and the annular ring.

In a nonlimiting illustrative embodiment, a semiconductor package comprises a semiconductor die and a redistribution layer. The redistribution layer includes a plurality of metallization layers and intermetal dielectric material, and has an under-bump metallization. The metallization layers of the redistribution layer electrically connect the semiconductor die with the under-bump metallization disposed on a surface of the redistribution layer. The under-bump metallization includes a bonding pad and a guard ring encircling the bonding pad. The guard ring forms an annular pocket encircling the bonding pad. The annular pocket is filled with a polymer material.

In a nonlimiting illustrative embodiment, a method is disclosed of manufacturing a semiconductor package. The method comprises: forming an under-bump metallization, including disposing a polymer layer on a substrate, patterning the polymer layer to form a patterned polymer layer having openings, and forming a bonding pad and a guard ring on the patterned polymer layer, the guard ring including an annular ring encircling the bonding pad and a connector ring connecting between the bonding pad and the annular ring; and forming a redistribution layer comprising a plurality of metallization layers embedded in intermetal dielectric material, the metallization layers of the redistribution layer electrically connecting a semiconductor die with the under-bump metallization.

In a nonlimiting illustrative embodiment, a method is disclosed of manufacturing a semiconductor package. The method includes forming an under-bump metallization, and forming a redistribution layer. The redistribution layer comprises a plurality of metallization layers embedded in intermetal dielectric material. The metallization layers of the redistribution layer electrically connect a semiconductor die with the under-bump metallization. The under-bump metallization includes a bonding pad and a guard ring encircling the bonding pad. The guard ring forms an annular pocket encircling the bonding pad. The annular pocket is filled with a polymer material.

In a nonlimiting illustrative embodiment, a method of manufacturing a semiconductor package is disclosed. The method comprises: forming an under-bump metallization on a surface of a first semiconductor component, the under-bump metallization including a set of bonding pads each encircled by a guard ring comprising an annular ring encircling the bonding pad and a connector ring connecting between the bonding pad and the annular ring, wherein an annular structure comprising a polymer material is located between the bonding pad and the annular ring; and bonding a second semiconductor component to the surface of the first semiconductor component using bonding bumps that bond to the bonding pads wherein each bonding bump bonds to a corresponding bonding pad but not to the annular ring encircling the corresponding bonding pad.

In a nonlimiting illustrative embodiment, a method is disclosed of attaching a second component comprising a semiconductor die or semiconductor package to a semiconductor package. The method includes: providing an under-bump metallization on a surface of the semiconductor package, the under-bump metallization including a set of bonding pads comprising an electrically conductive material wherein each bonding pad is encircled by a guard ring of the electrically conductive material that forms an annular pocket containing a polymer material; and bonding the second component to the surface of the semiconductor package using bonding bumps that bond to the bonding pads wherein each bonding bump bonds to a corresponding bonding pad but not to the guard ring of electrically conductive material encircling the corresponding bonding pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a semiconductor die;
a redistribution layer comprising a plurality of metallization layers and intermetal dielectric material;
an under-bump metallization disposed on the redistribution layer, the metallization layers of the redistribution layer electrically connecting the semiconductor die with the under-bump metallization, wherein the under-bump metallization includes a bonding pad and an annular ring encircling the bonding pad; and
an annular structure comprising a polymer material between the bonding pad and the annular ring.

2. The semiconductor package of claim 1, wherein the under-bump metallization further includes:
a buried connector ring connecting between the bonding pad and the annular ring, the buried connector ring being covered by the annular structure;
wherein the annular structure is bounded by the bonding pad, the annular ring, and the buried connector ring.

3. The semiconductor package of claim 2, wherein the under-bump metallization further includes:
a second annular ring encircling the annular ring, the buried connector ring further connecting between the annular ring and the second annular ring;
wherein a second annular structure is bounded by the annular ring, the second annular ring, and the buried connector ring, the second annular structure comprising the polymer material and the buried connector ring being covered by the second annular structure.

4. The semiconductor package of claim 2, wherein an annulus of the annular structure has a width between 30 microns and 40 microns inclusive and an annulus of the annular ring has a width between 10 microns and 40 microns inclusive.

5. The semiconductor package of claim 2, wherein the bonding pad, the annular ring, and the buried connector ring each comprise copper, aluminum, a copper alloy, or an aluminum alloy.

6. The semiconductor package of claim 1, wherein an annulus of the annular structure has a width between 30 microns and 40 microns inclusive.

7. The semiconductor package of claim 1, further comprising:
a pre-solder disposed on the bonding pad.

8. The semiconductor package of claim 1, further comprising:
a second component comprising a semiconductor die or semiconductor package; and
a bonding bump disposed on the bonding pad and electrically connecting the bonding pad with the second component.

9. The semiconductor package of claim 8, further comprising:
underfill material disposed between the under-bump metallization and the second component.

10. A method of manufacturing a semiconductor package, the method comprising:
forming an under-bump metallization, including:
disposing a polymer layer on a substrate;
patterning the polymer layer to form a patterned polymer layer having openings; and
forming a bonding pad and a guard ring on the patterned polymer layer, the guard ring including an annular ring encircling the bonding pad and a connector ring connecting between the bonding pad and the annular ring; and
forming a redistribution layer comprising a plurality of metallization layers embedded in intermetal dielectric material, the metallization layers of the redistribution layer electrically connecting a semiconductor die with the under-bump metallization.

11. The method of claim 10, wherein the guard ring forms an annular pocket encircling the bonding pad, the annular pocket being filled with a portion of the patterned polymer layer.

12. The method of claim 10, wherein the patterning the polymer layer is performed through a photolithography process.

13. The method of claim 10, wherein the forming the bonding pad and the guard ring includes performing copper plating.

14. The method of claim 10, further comprising:
depositing pre-solder on the bonding pad.
after depositing the pre-solder, attaching a second component comprising a semiconductor die to the under-bump metallization using a solder bump that attaches to the bonding pad via the pre-solder, the attaching leaving solder flux residue on the solder bump after the attaching is complete; and
disposing underfill material between the second component and the under-bump metallization.

15. The method of claim 10, further comprising:
attaching a second component comprising a semiconductor die or semiconductor package to the under-bump metallization wherein the attaching uses a solder bump that is disposed between the second component and the solder bump and is bonded to the bonding pad during the attaching; and
after the attaching, disposing underfill material between the second component and the under-bump metallization.

16. A method of manufacturing a semiconductor package, the method comprising:
forming an under-bump metallization on a surface of a first semiconductor component, the under-bump metallization including a set of bonding pads each encircled by a guard ring comprising an annular ring encircling the bonding pad and a connector ring connecting between the bonding pad and the annular ring, wherein an annular structure comprising a polymer material is located between the bonding pad and the annular ring; and
bonding a second semiconductor component to the surface of the first semiconductor component using bonding bumps that bond to the bonding pads wherein each bonding bump bonds to a corresponding bonding pad but not to the annular ring encircling the corresponding bonding pad.

17. The method of claim 16, further comprising:
after the bonding, disposing underfill material between the second semiconductor component and the surface of the first semiconductor component, the underfill material at least partially surrounding the bonding bumps.

18. The method of claim 16, wherein each bonding pad is further encircled by a second guard ring of the electrically conductive material, the second guard ring comprising a second annular ring encircling the annular ring and the connector ring further connecting between the annular ring and the second annular ring.

19. The method of claim 16, wherein the bonding pad and the guard ring are formed by copper plating.

20. The method of claim 16, wherein the guard ring forms an annular pocket encircling the bonding pad, the annular pocket being filled with the annular structure.
